(19) United States
(12) Patent Application Publication
(10) Pub. No.: US 2026/0096446 A1
(43) Pub. Date: Apr. 2, 2026

(54) MANUFACTURE METHOD FOR A PACKAGING SUBSTRATE

(71) Applicant: Absolics Inc., Covington, GA (US)

(72) Inventor: Jungju JO, Covington, GA (US)

(73) Assignee: Absolics Inc., Covington, GA (US)

(21) Appl. No.: 19/344,502

(22) Filed: Sep. 29, 2025

Related U.S. Application Data
(60) Provisional application No. 63/701,601, filed on Oct. 1, 2024.

(51) Int. Cl. H01L 21/48

(52) U.S. Cl. CPC H10W 70/05; H10W 70/095

(57) ABSTRACT

According to an embodiment, a method for manufacturing a packaging substrate comprises: a preparation step to comprise a base substrate including a core layer, a first conductive layer disposed on the core layer, and an insulating layer disposed on the first conductive layer; and a desmear step to comprise desmearing the base substrate, thereby providing a packaging substrate. The insulating layer comprises a contact hole penetrating the insulating layer in a thickness direction. An upper surface of the first conductive layer comprises an exposed region exposed by the contact hole. In the desmear step, the base substrate is plasma-desmeared using a reactive gas comprising oxygen gas and a fluorine-based gas. In the desmear step, a ratio of a flow rate of the fluorine-based gas to a flow rate of the oxygen gas introduced into an atmosphere in which the base substrate is placed is 4.5 or more.

### CROSS-REFERENCE TO RELATED APPLICATIONS

This application claims the priority benefit under 35 U.S.C. 119(e) of U.S. provisional Application No. 63/701,601 filed on Oct. 1, 2024. The entirety of the above-mentioned patent application is hereby incorporated by reference herein and made a part of this specification.

### TECHNICAL FIELD

The present disclosure relates to a method for manufacturing a packaging substrate.

### BACKGROUND

In manufacturing electronic components, implementing circuits on a semiconductor wafer is referred to as a front-end process (FE: Front-End), and assembling the wafer into a state in which it may be used in an actual product is referred to as a back-end process (BE: Back-End), wherein the packaging process is included in the back-end process.

Recently, the four core technologies of the semiconductor industry that enabled the rapid development of electronic products include semiconductor technology, semiconductor packaging technology, manufacturing process technology, and software technology. Although semiconductor technology has advanced in various forms such as linewidths of nanometer units below micrometers, tens of millions of cells, high-speed operation, and large heat dissipation, the technology to perfectly package the same has not been relatively supported. Accordingly, the electrical performance of a semiconductor is sometimes determined by the packaging technology and the electrical connection resulting therefrom rather than the performance of the semiconductor technology itself.

As materials for packaging substrates, ceramics or resins are applied. In the case of ceramic substrates, due to high resistance or high dielectric constant, it is not easy to mount high-performance high-frequency semiconductor devices. In the case of resin substrates, although high-performance high-frequency semiconductor devices may be mounted relatively, there is a limitation in reducing wiring pitch.

Recently, studies have been conducted on applying silicon or glass as high-end packaging substrates. A through-hole is formed in a silicon or glass substrate, and a conductive material is applied to the through-hole, so that the wiring length between the device and the motherboard becomes shorter, and excellent electrical characteristics may be obtained.

### SUMMARY

A method for manufacturing a packaging substrate according to one embodiment of the present specification comprises:
a preparation step of providing a base substrate including a core layer, a first conductive layer disposed on the core layer, and an insulating layer disposed on the first conductive layer; and
a desmear step of desmearing the base substrate,
wherein the packaging substrate is provided.

The insulating layer includes a contact hole penetrating the insulating layer in a thickness direction.

An upper surface of the first conductive layer includes an exposed region exposed by the contact hole.

In the desmear step, the base substrate is plasma-desmeared using a reactive gas including oxygen gas and a fluorine-based gas.

In the desmear step, a ratio of a flow rate of the fluorine-based gas to a flow rate of the oxygen gas introduced into an atmosphere in which the base substrate is placed is 4.5 or more.

A difference value between a thickness of the insulating layer before the desmear step and a thickness of the insulating layer after the desmear step may be 0.7 μm or less.

An arithmetic average roughness Ra value of an upper surface of the insulating layer in the base substrate after completion of the desmear step may be 125 nm or less.

A maximum height roughness Rz value of an upper surface of the insulating layer in the base substrate after completion of the desmear step may be 4.5 μm or less.

The insulating layer may include a filler.

An average particle diameter (D50) of the filler may be 1 μm or less.

A maximum particle diameter of the filler may be 10 μm or less.

The contact hole may include a first opening disposed at an upper surface side of the insulating layer, a second opening disposed at a lower surface side of the insulating layer, and an inner surface of the insulating layer formed in the thickness direction of the insulating layer connecting the first opening and the second opening.

A diameter of the first opening may be larger than a diameter of the second opening.

A ratio of the diameter of the first opening to the diameter of the second opening may be 1.1 or more.

The method for manufacturing a packaging substrate may further comprise a conductive layer forming step of forming a second conductive layer on the insulating layer in the base substrate after completion of the desmear step.

The conductive layer forming step may include a seed layer forming process of forming a seed layer on the inner surface of the insulating layer and a conductor layer forming process of forming a conductor layer on the seed layer to provide the second conductive layer.

The seed layer may include any one selected from the group consisting of titanium, tungsten, tantalum, molybdenum, nickel, chromium, and a combination thereof.

A peel strength of the second conductive layer with respect to an upper surface of the insulating layer may be 400 gf/cm or more.

### BRIEF DESCRIPTION OF THE DRAWINGS

FIG. 1 is a cross-sectional view of a base substrate prepared through the preparation step of the present disclosure.

FIG. 2A is a conceptual diagram illustrating a seed layer prepared through the seed layer forming process of the present disclosure.

FIG. 2B is a conceptual diagram illustrating a packaging substrate of the present disclosure.

### DETAILED DESCRIPTION

Hereinafter, exemplary embodiments will be described in detail with reference to the accompanying drawings so that those skilled in the art to which the present invention pertains may easily implement the present invention. However, the present invention may be implemented in various different forms and is not limited to the embodiments described herein. The same reference numerals are assigned to similar parts throughout the specification.

Throughout the present specification, the term “a combination thereof” included in Markush-type expressions means a mixture or combination of one or more selected from the group consisting of the components described in the Markush-type expressions, and means that one or more selected from the group consisting of the components are included.

In the present specification, terms such as “first,” “second,” or “A,” “B” are used to distinguish the same terms from each other. In addition, singular expressions include plural expressions unless the context clearly indicates otherwise.

In the present specification, the term “˜ based” may mean that a compound corresponding to “˜” or a derivative thereof is included in the compound.

In the present specification, the meaning that B is located on A includes a case in which B is located directly on A or B is located on A while another layer is interposed therebetween, and is not to be construed as limited to a case in which B is located in contact with a surface of A.

In the present specification, the meaning that A is connected to B includes a case in which A and B are directly connected or connected through another component interposed therebetween, and unless otherwise specified, is not to be construed as limited to a case in which A and B are directly connected.

In the present specification, unless otherwise described, singular expressions are to be interpreted as including both singular and plural as understood in the context.

In the present specification, shapes, relative sizes, angles, and the like of each component in the drawings may be exaggerated for the purpose of explanation as exemplary, and the rights are not to be construed as limited to the drawings.

In the present specification, the expression that A and B are adjacent means that A and B are located in contact with each other, or not in contact but located close to each other. The expression that A and B are adjacent is not to be construed as limited to a case in which A and B are located in contact with each other unless otherwise specified.

In the present specification, unless otherwise described, physical property values of each component in the packaging substrate are interpreted as those measured at room temperature. The room temperature is 20° C. to 25° C.

After forming a contact hole in the insulating layer, plasma desmearing may be performed to remove residues such as particles in the contact hole. However, when a conductive layer is formed on the upper surface of the insulating layer after completing the desmear, stable bonding strength between the insulating layer and the conductive layer may not be formed. It is considered that this is because the upper surface of the insulating layer is excessively roughened during the desmear process.

The inventors of the present disclosure applied technical features such as adjusting the flow rate ratio of reactive gases during the desmear process. Through this, the inventors experimentally confirmed that stable bonding strength between the insulating layer after completing the desmear and a conductive layer disposed on the insulating layer may be formed while effectively removing residues in the contact hole, thereby completing the present disclosure.

Hereinafter, the present disclosure will be described in detail.

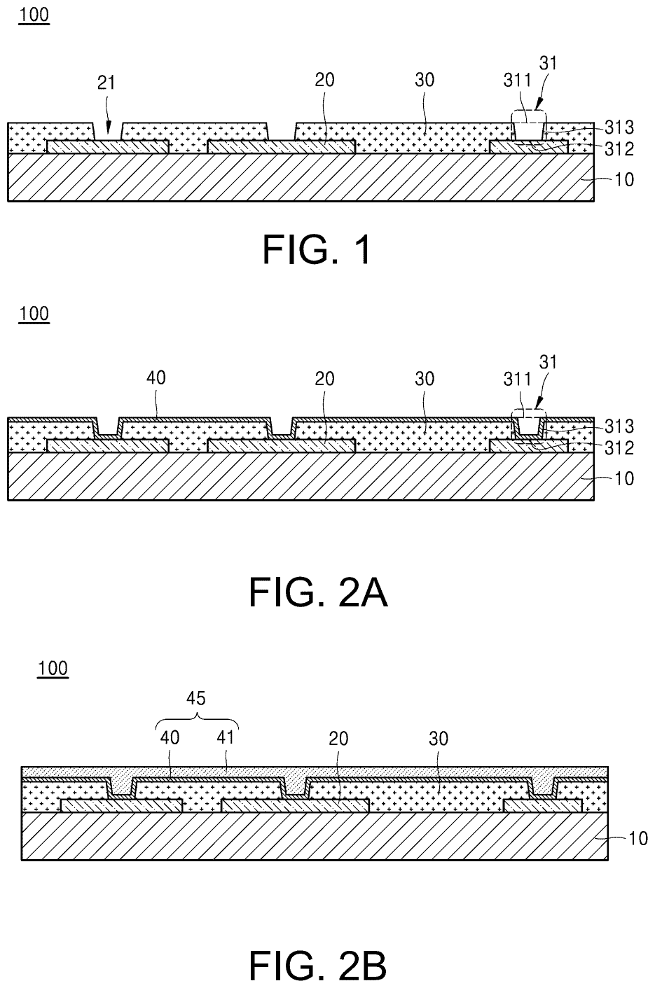

FIG. 1 is a cross-sectional view of a base substrate prepared through the preparation step. Hereinafter, the present disclosure will be described with reference to FIG. 1.

A method for manufacturing a packaging substrate of the present disclosure comprises: a preparation step of providing a base substrate 100 including a core layer 10, a first conductive layer 20 disposed on the core layer 10, and an insulating layer 30 disposed on the first conductive layer 20; and a desmear step of desmearing the base substrate 100, thereby providing a packaging substrate.

### Preparation Step

In the preparation step, the base substrate 100 may be provided.

The base substrate 100 may include a core layer 10. The core layer 10 may have a substrate shape and may serve as a support layer in the packaging substrate. The core layer 10 is not limited as long as it may be applied in the field of packaging substrates. For example, the core layer 10 may be an organic substrate, a glass fiber impregnated substrate, a ceramic substrate, or a glass substrate.

A thickness of the core layer 10 may be 100 μm or more. The thickness may be 200 μm or more. The thickness may be 300 μm or more. The thickness may be 3000 μm or less. The thickness may be 2000 μm or less. The thickness may be 1000 μm or less. In this case, the core layer 10 may have mechanical properties suitable for being applied to a packaging substrate.

The base substrate 100 may include the first conductive layer 20 disposed on the core layer 10 and the insulating layer 30 disposed on the first conductive layer 20.

In the preparation step, a base substrate 100 in which the first conductive layer 20 and the insulating layer 30 are already formed on the core layer 10 may be introduced. The base substrate 100 may be prepared by forming the insulating layer 30 on a substrate on which the core layer 10 and the first conductive layer 20 are already formed. The base substrate 100 may be prepared by forming the first conductive layer 20 and the insulating layer 30 on the core layer 10.

The first conductive layer 20 may be formed in contact with the upper surface of the core layer 10, and another component such as the insulating layer 30 may be disposed between the first conductive layer 20 and the core layer 10, so that the first conductive layer 20 may be disposed spaced apart from the upper surface of the core layer 10.

When forming the first conductive layer 20 on the core layer 10, the first conductive layer 20 may be formed by a dry method or a wet method.

The dry method is a method of forming a seed layer by sputtering on a region of the core layer 10 where the first conductive layer 20 is to be disposed, and forming a conductive layer by plating on the region where the seed layer is formed. In forming the seed layer, a metal including any one selected from the group consisting of titanium, tungsten, tantalum, molybdenum, nickel, chromium, and a combination thereof may be sputtered, and the metals may be sputtered together with copper. Through sputtering, an anchor effect in which the surface on which the first conductive layer 20 is to be disposed interacts with deposited metal particles may appear, thereby improving the adhesion of the first conductive layer 20.

The wet method is a method of performing metal plating after treating a primer on a portion where the first conductive layer 20 needs to be formed. The primer may include a compound having a functional group such as an amine. Depending on the degree of adhesion intended, the primer may include a compound having a functional group such as an amine together with a silane coupling agent. When applying the silane coupling agent, after pretreating a surface to be treated with a silane coupling agent, the primer layer may be formed by coating the pretreated region with a compound having an amine group.

After forming the seed layer or the primer layer, the first conductive layer 20 may be formed by plating a metal. In forming the first conductive layer 20, copper plating may be applied, but is not limited thereto. Prior to metal plating, a portion where the first conductive layer 20 does not need to be formed in the seed layer or the primer layer may be inactivated, or a portion where the first conductive layer 20 needs to be formed may be activated, and then plating may be performed. As a method of activation or inactivation treatment, light irradiation treatment by irradiating a laser of a specific wavelength or chemical treatment may be applied. However, after performing metal plating without applying activation or inactivation treatment, the first conductive layer 20 may be etched and patterned according to a pre-designed shape.

The insulating layer 30 may be disposed on the first conductive layer 20. The insulating layer 30 may be formed to surround at least a portion of the first conductive layer 20. The insulating layer 30 may be formed to surround at least a portion of the upper surface of the first conductive layer 20. The insulating layer 30 may be formed to surround at least a portion of the upper surface and the side surface of the first conductive layer 20.

The insulating layer 30 and the first conductive layer 20 may be disposed mixed on the core layer 10. The first conductive layer 20 having a patterned shape may be formed in a form embedded in the insulating layer 30.

The insulating layer 30 may be applicable as long as it may be applied as an insulating layer in the field of packaging substrates. For example, the insulating layer 30 may be formed of an epoxy-based resin including a filler. For example, the insulating layer 30 may be formed through a build-up layer material such as ABF (Ajinomoto Build-up Film) of Ajinomoto, an undercoat material, and the like, but is not limited thereto.

The insulating layer 30 may include a filler. The filler is not limited as long as it may be conventionally applied in the field of insulating layers. For example, the filler may include silica, alumina, titania, or the like.

The present disclosure may control the average particle diameter (D50) of the filler within a predetermined range. In this case, even if the resin contained in the insulating layer 30 is more etched than the filler due to a difference in etching characteristics between the filler and the resin contained in the insulating layer 30 during the desmear step, excessive roughening of the upper surface of the insulating layer 30 may be prevented.

The average particle diameter (D50) of the filler may be 1 μm or less. The average particle diameter may be 0.9 μm or less. The average particle diameter may be 0.8 μm or less. The average particle diameter may be 0.7 μm or less. The average particle diameter may be 0.1 μm or more.

The maximum particle diameter of the filler may be 10 μm or less. The maximum particle diameter may be 9 μm or less. The maximum particle diameter may be 8 μm or less. The maximum particle diameter may be 7 μm or less. The maximum particle diameter may be 0.1 μm or more.

In this case, stable bonding strength between the insulating layer 30 and a conductive layer formed on the insulating layer 30 may be helped to form.

When forming the insulating layer 30 on the first conductive layer 20, the insulating layer 30 may be formed by laminating an uncured or semi-cured insulating film and then curing it.

The insulating layer 30 may include a contact hole 31 penetrating the insulating layer 30 in the thickness direction. The contact hole 31 may provide a space for forming a conductive layer in the thickness direction of the packaging substrate. A conductive layer formed in the contact hole 31 may electrically connect the first conductive layer 20 and a conductive layer formed on the first conductive layer 20.

The contact hole 31 may expose a portion of the upper surface of the first conductive layer 20. The upper surface of the first conductive layer 20 may include an exposed region 21 exposed by the contact hole 31.

The contact hole 31 may include a first opening 311 disposed on the upper surface side of the insulating layer 30, a second opening 312 disposed on the lower surface side of the insulating layer 30, and an inner surface 313 of the insulating layer formed in the thickness direction of the insulating layer 30 connecting the first opening 311 and the second opening 312.

The inner surface 313 of the insulating layer may form an inclined surface. When observing the base substrate 100 in cross-section, the profile of the inner surface 313 of the insulating layer may be a straight line, a curved line, or may include both a straight line and a curved line.

The present disclosure may adjust the diameter of the first opening 311 to be larger than the diameter of the second opening 312. Through this, plasma gas may smoothly reach into the contact hole 31 during the desmear step, thereby effectively removing residues in the contact hole 31. In addition, a seed layer may be easily formed with a relatively uniform thickness on the inner surface 313 of the insulating layer through sputtering or the like.

A ratio of the diameter of the first opening 311 to the diameter of the second opening 312 may be 1.1 or more. The ratio may be 1.15 or more. The ratio may be 1.2 or more. The ratio may be 1.3 or more. The ratio may be 3 or less. In this case, the formation of a conductive layer having excellent electrical reliability and durability in the contact hole 31 may be assisted.

When observing the base substrate 100 in cross-section in the thickness direction, an angle formed by the profile of the inner surface 313 of the insulating layer and the profile of the exposed region 21 may be 92 degrees or more. The angle may be 95 degrees or more. The angle may be 120 degrees or less. The angle may be 115 degrees or less. In this case, the desmear process may be smoothly assisted, and formation of voids in the process of forming a conductive layer in the contact hole 31 may be suppressed.

When the profile of the inner surface 313 of the insulating layer includes a curved surface, a method for measuring the angle formed by the profile of the inner surface 313 of the insulating layer and the profile of the exposed region 21 is as follows. A first point, which is a point where the profile of the inner surface 313 of the insulating layer and the profile of the upper surface of the insulating layer 30 meet, and a second point, which is a point where the profile of the inner surface 313 of the insulating layer and the profile of the lower surface of the insulating layer 30 meet, are specified. The angle formed by a straight line connecting the first point and the second point and the profile of the exposed region 21 is measured, and the measured angle is defined as the angle formed by the profile of the inner surface 313 of the insulating layer and the profile of the exposed region 21.

The contact hole 31 may be formed by etching a region in which the contact hole 31 is to be disposed in the insulating layer 30. The contact hole 31 may be formed through laser etching, dry etching, wet etching, or the like. For precise control of the shape of the contact hole 31, laser etching may be applied.

### Desmear Step

### Process Conditions

A method for manufacturing a packaging substrate of the present disclosure includes a desmear step of desmearing the base substrate 100. In the desmear step, the base substrate 100 is plasma-desmeared using a reactive gas including oxygen gas and a fluorine-based gas. Specifically, in the desmear step, the reactive gas is introduced into an atmosphere in which the base substrate 100 is placed, and the base substrate 100 is plasma-etched with the reactive gas to remove residues in the contact hole 31.

The oxygen gas may exhibit relatively high etching characteristics with respect to the resin included in the insulating layer 30. The fluorine-based gas may exhibit relatively high etching characteristics with respect to the filler included in the insulating layer 30.

The fluorine-based gas may be a fluorinated carbon compound. The fluorine-based gas may be any one selected from the group consisting of CF₄, C₂F₂, C₂F₄, C₂F₆, C₃F₆, C₃F₈, C₄F₈, C₄F₁₀, and a combination thereof. The fluorine-based gas may be CF₄.

The present disclosure may control the ratio of the flow rate of the fluorine-based gas to the flow rate of the oxygen gas introduced into the atmosphere in which the base substrate 100 is placed within a predetermined range. In this case, excessive roughening of the upper surface of the insulating layer 30 may be suppressed by preventing an excessive difference in etching speed between the resin and the filler included in the insulating layer 30 during the desmear step.

In the desmear step, the ratio of the flow rate of the fluorine-based gas to the flow rate of the oxygen gas introduced into the atmosphere in which the base substrate 100 is placed may be 4.5 or more. The ratio may be 4.7 or more. The ratio may be 5 or more. The ratio may be 8 or more. The ratio may be 10 or more. The ratio may be 12 or more. The ratio may be 15 or more. The ratio may be 17 or more. The ratio may be 20 or more. The ratio may be 25 or more. The ratio may be 30 or more. The ratio may be 35 or more. The ratio may be 80 or less. In this case, the resin in the insulating layer 30 may be prevented from being excessively etched compared to the filler during the desmear step.

In the desmear step, the flow rate of the oxygen gas introduced into the atmosphere in which the base substrate 100 is placed may be 400 sccm or less. The flow rate may be 350 sccm or less. The flow rate may be 300 sccm or less. The flow rate may be 250 sccm or less. The flow rate may be 10 sccm or more.

In the desmear step, the flow rate of the fluorine-based gas introduced into the atmosphere in which the base substrate 100 is placed may be 45 sccm or more. The flow rate may be 100 sccm or more. The flow rate may be 200 sccm or more. The flow rate may be 300 sccm or more. The flow rate may be 400 sccm or more. The flow rate may be 500 sccm or more. The flow rate may be 600 sccm or more. The flow rate may be 700 sccm or more. The flow rate may be 800 sccm or more. The flow rate may be 2,000 sccm or less.

In this case, it may contribute to providing a reactive gas with a reduced difference in etching characteristics between the resin and the filler in the insulating layer 30.

The reactive gas may further include other gases in addition to the oxygen gas and the fluorine-based gas as needed.

In the desmear step, a plasma beam may be irradiated onto the reactive gas to form a plasma gas. The discharge power applied to the plasma beam may be 3,000 W or more. The discharge power may be 4,000 W or more. The discharge power may be 5,000 W or more. The discharge power may be 6,000 W or more. The discharge power may be 10,000 W or less.

A frequency applied to the plasma beam may be 10 kHz or more. The frequency may be 20 kHz or more. The frequency may be 30 kHz or more. The frequency may be 200 kHz or less. The frequency may be 150 kHz or less. The frequency may be 100 kHz or less.

In this case, it may help form a sufficient amount of reactive gas in the atmosphere in which the base substrate 100 is placed.

The discharge power is the discharge power per nozzle from which the plasma beam is emitted.

In the desmear step, by controlling the distance between the base substrate and the electrode generating plasma, residues in the contact hole may be sufficiently removed while suppressing excessive damage to the upper surface of the insulating layer.

In the desmear step, the distance between the base substrate and the electrode may be 150 mm or less. The distance may be 120 mm or less. The distance may be 100 mm or less. The distance may be 80 mm or less. The distance may be 60 mm or less. The distance may be 10 mm or more. The distance may be 20 mm or more. In this case, it may contribute to forming a rewiring layer having excellent electrical reliability in the base substrate 100.

### Characteristics of the Insulating Layer After Completing the Desmear Step

The present disclosure may control the difference in thickness of the insulating layer 30 before and after performing the desmear step. Specifically, the difference in thickness may be controlled within a predetermined range of the thickness of the insulating layer 30 etched by the plasma gas in the desmear step. In this case, excessive damage to the upper surface side of the insulating layer 30 by the plasma gas may be suppressed. In particular, roughening of the upper surface of the insulating layer 30 beyond a certain level by the plasma gas may be suppressed, and it may be prevented that the insulating layer 30 has a thickness thinner than the intended thickness.

The thickness of the insulating layer 30 before the desmear step and the thickness of the insulating layer 30 after completing the desmear step are measured at the same position in the insulating layer 30. The thickness measuring position of the insulating layer 30 is specified as a position where a contact hole 31 is not formed in the insulating layer 30.

The difference value between the thickness of the insulating layer 30 before the desmear step and the thickness of the insulating layer 30 after completing the desmear step may be 0.7 μm or less. The value may be 0.5 μm or less. The value may be 0.4 μm or less. The value may be 0.3 μm or less. The value may be 0.2 μm or less. The value may be 0 μm or more. In this case, excessive damage to the upper surface side of the insulating layer 30 by the plasma gas may be suppressed.

The present disclosure may control the roughness characteristics of the upper surface of the insulating layer 30 to reduce the influence of irregularities located on the upper surface of the insulating layer 30 on the bonding strength between the upper surface of the insulating layer 30 and the conductive layer.

An arithmetic average roughness Ra value of the upper surface of the insulating layer 30 in the base substrate 100 after completing the desmear step may be 125 nm or less. The Ra value may be 115 nm or less. The Ra value may be 100 nm or less. The Ra value may be 80 nm or less. The Ra value may be 60 nm or less. The Ra value may be 50 nm or less. The Ra value may be 40 nm or less. The Ra value may be 30 nm or less. The Ra value may be 10 nm or more.

A maximum height roughness Rz value of the upper surface of the insulating layer 30 in the base substrate 100 after completing the desmear step may be 4.5 μm or less. The Rz value may be 4.3 μm or less. The Rz value may be 4.0 μm or less. The Rz value may be 3.5 μm or less. The Rz value may be 3.0 μm or less. The Rz value may be 2.5 μm or less. The Rz value may be 2.0 μm or less. The Rz value may be 1.5 μm or less. The Rz value may be 1.0 μm or less. The Rz value may be 0.05 μm or more.

In this case, an environment suitable for forming stable bonding strength between the upper surface of the insulating layer 30 and the conductive layer may be provided.

The Ra value and the Rz value are measured according to ISO4287:1997.

### Conductive Layer Forming Step

FIG. 2A is a conceptual diagram illustrating a seed layer prepared through the seed layer forming process of the present disclosure. FIG. 2B is a conceptual diagram illustrating a packaging substrate of the present disclosure. Hereinafter, the present disclosure will be described with reference to FIGS. 2A and 2B.

The above description in FIG. 1 regarding the base substrate 100, the core layer 10, the first conductive layer 20, the insulating layer 30, and the contact hole 31 is also applied to FIGS. 2A and 2B. Hereinafter, descriptions will focus on the parts where differences exist.

A method for manufacturing a packaging substrate of the present disclosure may further comprise a conductive layer forming step of forming a second conductive layer 45 on the insulating layer 30 in the base substrate 100 after completing the desmear step.

The second conductive layer 45 is distinguished from the first conductive layer 20 formed below the insulating layer 30 in that the second conductive layer 45 is formed on the insulating layer 30 and in the contact hole 31.

The second conductive layer 45 may include a seed layer 40 and a conductor layer 41 disposed on the seed layer 40. The conductor layer 41 may be disposed in contact with the seed layer 40.

The seed layer 40 may include any one selected from the group consisting of titanium, tungsten, tantalum, molybdenum, nickel, chromium, and a combination thereof. The seed layer 40 may include a first seed layer 40 and a second seed layer disposed on the first seed layer. The first seed layer may include any one selected from the group consisting of titanium, tungsten, tantalum, molybdenum, nickel, chromium, and a combination thereof. The second seed layer may include the same metal element as a metal element applied to the conductor layer 41. The second seed layer may include copper. A seed layer 40 having such a structure and composition may help the second conductive layer 45 have excellent bonding strength to the insulating layer 30.

The conductor layer 41 may include copper.

The conductive layer forming step of the present disclosure may include a seed layer forming process of forming the seed layer 40 on the inner surface 313 of the insulating layer and a conductor layer forming process of forming the conductor layer 41 on the seed layer 40 to provide the second conductive layer 45. Specifically, in the seed layer forming process, the present disclosure may form the seed layer 40 having a uniformized thickness distribution on the inner surface 313 of the insulating layer with an adjusted inclination angle. Through this, bonding defects between the inner surface 313 of the insulating layer and the seed layer 40 may be suppressed, and the second conductive layer 45 may be stably fixed in the contact hole 31 of the insulating layer 30.

Except for forming the seed layer 40 on the inner surface 313 of the insulating layer and the thickness of the layer, the second conductive layer 45 may be prepared in the same manner as the method of forming the first conductive layer 20. Detailed description of the method of forming the second conductive layer 45 is omitted since it is duplicated with the previous description.

A peel strength of the second conductive layer 45 with respect to the upper surface of the insulating layer 30 may be 400 gf/cm or more. The peel strength may be 500 gf/cm or more. The peel strength may be 600 gf/cm or more. The peel strength may be 650 gf/cm or more. The peel strength may be 700 gf/cm or more. The peel strength may be 1,000 gf/cm or less. In this case, the second conductive layer 45 may be stably fixed on the insulating layer 30.

The peel strength is measured as follows. The second conductive layer 45 on the insulating layer 30 is cut into a width of 10 mm and a length of 100 mm, and then one end of the cut second conductive layer 45 in the longitudinal direction is pulled at an angle of 90 degrees with respect to the upper surface of the insulating layer 30 to measure the peel strength.

The present disclosure may manufacture a packaging substrate by forming the second conductive layer 45 on the insulating layer 30.

If necessary, the conductive layer forming step of the present disclosure may further comprise a process of forming another insulating layer 30 disposed on the second conductive layer 45 and another conductive layer disposed on the insulating layer 30. If necessary, the conductive layer forming step of the present disclosure may further comprise a process of forming another insulating layer 30 disposed under the core layer 10 and another conductive layer disposed under the insulating layer 30. The insulating layer 30 and the conductive layer may be prepared in the same manner as described above.

### Other Steps

If necessary, an upper terminal and the like may be additionally formed on an upper portion and/or a lower portion of the packaging substrate, and bumps may be additionally formed on a lower portion of the packaging substrate. The bumps may be disposed in a predetermined form below a redistribution layer, which is a layer including the insulating layer 30 and a conductive layer disposed below the core layer 10. For example, the bumps may be disposed on a part of the lower surface of the packaging substrate so as to be in contact with a main board or the like.

Hereinafter, the present disclosure will be described in more detail through specific embodiments. The following embodiments are merely examples for helping understanding of the present disclosure, and the scope of the present disclosure is not limited thereto.

### Preparation Example: Formation of Packaging Substrate

Example 1: A CCL (Copper Clad Laminate) having a thickness of 0.5 mm was prepared. On both surfaces of the CCL, an insulating layer was prepared by laminating and curing ABF GL103, which is a build-up film having a thickness of 20 μm (average particle diameter (D50) of filler in the film: 0.5 μm, maximum particle diameter: 5 μm). A base substrate was prepared by forming a plurality of contact holes in the insulating layer formed on both surfaces of the CCL with a UV laser. The diameter of the first opening of the contact hole was applied as 40 μm. It was confirmed that the contact hole was formed in a tapered shape in which the first opening was larger than the second opening.

After inserting the base substrate into a chamber, plasma desmear was performed for 60 seconds. During desmear, the discharge power of a nozzle emitting a plasma beam was applied as 7000 W, the frequency was 50 kHz, the flow rate of oxygen gas introduced into the chamber was 20 sccm, the flow rate of CF₄, which is a fluorine-based gas, was 1,000 sccm, and the distance between the base substrate and the electrode was applied as 40 mm.

On the upper surface of the insulating layer of the base substrate after desmear, the inner surface of the insulating layer, and the surface of the CCL exposed by the contact hole, a first seed layer of titanium having a thickness of 150 nm was formed through sputtering, and on the first seed layer, a second seed layer of copper having a thickness of 300 nm was formed through sputtering. On the second seed layer, an electroless plating process was performed to fill the inside of the contact hole with a copper layer and to form a copper layer having a thickness of 20 μm on the upper surface of the insulating layer, thereby preparing a conductor layer and completing the second conductive layer.

Example 2: A packaging substrate was prepared under the same conditions as Example 1 except that the flow rate of oxygen gas during plasma desmear was applied as 50 sccm.

Example 3: A packaging substrate was prepared under the same conditions as Example 1 except that the flow rate of oxygen gas during plasma desmear was applied as 200 sccm.

Example 4: A packaging substrate was prepared under the same conditions as

Example 1 except that plasma desmear was performed for 90 seconds and the flow rate of oxygen gas was applied as 50 sccm.

Example 5: A packaging substrate was prepared under the same conditions as Example 4 except that the flow rate of oxygen gas during plasma desmear was applied as 100 sccm.

Example 6: A packaging substrate was prepared under the same conditions as Example 4 except that the flow rate of oxygen gas during plasma desmear was applied as 200 sccm.

Example 7: A packaging substrate was prepared under the same conditions as Example 1 except that plasma desmear was performed for 120 seconds and the flow rate of oxygen gas was applied as 50 sccm.

Example 8: A packaging substrate was prepared under the same conditions as Example 7 except that the flow rate of oxygen gas during plasma desmear was applied as 100 sccm.

Example 9: A packaging substrate was prepared under the same conditions as

Example 7 except that the flow rate of oxygen gas during plasma desmear was applied as 200 sccm.

Example 10: A packaging substrate was prepared under the same conditions as Example 1 except that plasma desmear was performed for 180 seconds and the flow rate of oxygen gas was applied as 50 sccm.

Comparative Example 1: A packaging substrate was prepared under the same conditions as Example 1 except that the flow rate of oxygen gas during plasma desmear was applied as 1,000 sccm and the flow rate of CF₄ was applied as 100 sccm.

Each process condition of the respective Examples and Comparative Examples is described in Table 1 below.

### Evaluation Example: Evaluation of Degree of Damage on Upper Side of Insulating Layer

In the manufacturing process of the packaging substrate of each Example and Comparative Example, the thickness of the insulating layer was measured before performing plasma desmear. Thereafter, after completing plasma desmear, the thickness of the insulating layer was measured. After the measurement, the difference value between the two thicknesses was calculated.

The measurement values of each Example and Comparative Example are described in Table 2 below.

### Evaluation Example: Evaluation of Roughness Characteristics of Upper Surface of Insulating Layer

In the manufacturing process of the packaging substrate of each Example and Comparative Example, after completing plasma desmear and before forming the first seed layer, the arithmetic average roughness (Ra value) and the maximum height roughness (Rz value) of the upper surface of the insulating layer were measured based on ISO4287:1997.

The measurement values of each Example and Comparative Example are described in Table 2 below.

### Evaluation Example: Evaluation of Peel Strength of Second Conductive Layer with Respect to Insulating Layer

In each Example and Comparative Example, the second conductive layer of the packaging substrate was cut into a size of a width of 10 mm and a length of 100 mm on the insulating layer, and then one end of the second conductive layer in the longitudinal direction was pulled at an angle of 90 degrees with respect to the upper surface of the packaging substrate to measure the peel strength of the second conductive layer with respect to the insulating layer.

The evaluation results of each Example and Comparative Example are described in Table 2 below.

### Evaluation Example: QVP (Quick Via Pull) Evaluation

After peeling the second conductive layer of the packaging substrate of each Example and Comparative Example, the inside of the contact hole was observed with an SEM (Scanning Electron Microscope). When the copper layer of the CCL was observed on the bottom surface of the contact hole, it was evaluated as Fail. When a part of the second conductive layer was observed on the bottom surface of the contact hole, or an organic layer disposed below the copper layer of the CCL was observed, it was evaluated as Pass.

The evaluation results of each Example and Comparative Example are described in Table 2 below.

TABLE 1

| | Desmear time (sec) | O₂ flow rate (sccm) | CF₄ flow rate (sccm) |
|---|---|---|---|
| Example 1 | 60 | 20 | 1,000 |
| Example 2 | 60 | 50 | 1,000 |
| Example 3 | 60 | 200 | 1,000 |
| Example 4 | 90 | 50 | 1,000 |
| Example 5 | 90 | 100 | 1,000 |
| Example 6 | 90 | 200 | 1,000 |
| Example 7 | 120 | 50 | 1,000 |
| Example 8 | 120 | 100 | 1,000 |
| Example 9 | 120 | 200 | 1,000 |
| Example 10 | 180 | 50 | 1,000 |
| Comparative Example 1 | 60 | 1,000 | 100 |

TABLE 2

| | Thickness difference value of | Ra | Rz | Peel strength | QVP |
|---|---|---|---|---|---|
| | insulating layer (μm) | (nm) | (μm) | (gf/cm) | test |
| Example 1 | 0 | 20.6 | 0.33 | 600.2 | Pass |
| Example 2 | 0.19 | 38.4 | 0.52 | 662.45 | Pass |
| Example 3 | 0.216 | 38.4 | 0.52 | 625.92 | Pass |
| Example 4 | 0.10 | 95.2 | 2.27 | 603.67 | Pass |
| Example 5 | 0.35 | 112.5 | 1.97 | 720.61 | Pass |
| Example 6 | 0.33 | 121.3 | 3.49 | 637.65 | Pass |
| Example 7 | 0.23 | 105.8 | 2.91 | 656.96 | Pass |
| Example 8 | 0.24 | 105.5 | 2.93 | 683.41 | Pass |
| Example 9 | 0.26 | 67.9 | 2.63 | 685.84 | Pass |
| Example 10 | 0.13 | 68.5 | 2.38 | 716.85 | Pass |
| Comparative | 1 | 140.4 | 5.1 | 60.4 | Fail |
| Example 1 | | | | | |

In Table 2 above, Examples 1 to 10 showed a peel strength of 600 gf/cm or more, whereas Comparative Example 1 showed a peel strength of 100 gf/cm or less. This result indicates that when the roughness characteristics of the upper surface of the insulating layer are controlled within a predetermined range in the present disclosure, the bonding strength of the second conductive layer to the upper surface of the insulating layer may be significantly improved.

In the QVP test, all of Examples 1 to 10 were evaluated as Pass, whereas Comparative Example 1 was evaluated as Fail. This is considered because, in the case of Examples 1 to 10, residues in the contact hole were substantially removed through desmear so that the second conductive layer and the copper layer of the CCL were stably connected, whereas in the case of Comparative Example 1, residues in the contact hole were not sufficiently removed, thereby causing defects in the electrical connection between the second conductive layer and the copper layer of the CCL.

Although preferred embodiments of the present invention have been described in detail above, the scope of rights of the present invention is not limited thereto, and various modifications and improved forms by those skilled in the art using the basic concepts of the present invention defined in the following claims also belong to the scope of rights of the present invention.

What is claimed is:

1. A method for manufacturing a packaging substrate, comprising:
a preparation step to comprise a base substrate including a core layer, a first conductive layer disposed on the core layer, and an insulating layer disposed on the first conductive layer; and
a desmear step to comprise desmearing the base substrate,
wherein the insulating layer comprises a contact hole penetrating the insulating layer in a thickness direction,
an upper surface of the first conductive layer comprises an exposed region exposed by the contact hole,
in the desmear step, the base substrate is plasma-desmeared using a reactive gas comprising oxygen gas and a fluorine-based gas, and
a ratio of a flow rate of the fluorine-based gas to a flow rate of the oxygen gas introduced into an atmosphere in which the base substrate is placed in the desmear step is 4.5 or more.

2. The method for manufacturing a packaging substrate according to claim 1,
wherein a difference value between a thickness of the insulating layer before the desmear step and a thickness of the insulating layer after the desmear step is 0.7 μm or less.

3. The method for manufacturing a packaging substrate according to claim 1,
wherein an arithmetic average roughness Ra value of an upper surface of the insulating layer in the base substrate after completion of the desmear step is 125 nm or less.

4. The method for manufacturing a packaging substrate according to claim 1,
wherein a maximum height roughness Rz value of an upper surface of the insulating layer in the base substrate after completion of the desmear step is 4.5 μm or less.

5. The method for manufacturing a packaging substrate according to claim 1,
wherein the insulating layer comprises a filler, and
an average particle diameter (D50) of the filler is 1 μm or less.

6. The method for manufacturing a packaging substrate according to claim 5,
wherein a maximum particle diameter of the filler is 10 μm or less.

7. The method for manufacturing a packaging substrate according to claim 1,
wherein the contact hole comprises a first opening disposed on an upper surface side of the insulating layer, a second opening disposed on a lower surface side of the insulating layer, and an inner surface of the insulating layer formed in a thickness direction of the insulating layer and connecting the first opening and the second opening,
and a diameter of the first opening is larger than a diameter of the second opening.

8. The method for manufacturing a packaging substrate according to claim 7,
wherein a ratio of the diameter of the first opening to the diameter of the second opening is 1.1 or more.

9. The method for manufacturing a packaging substrate according to claim 7,
wherein the method further comprises a conductive layer forming step of forming a second conductive layer on the insulating layer in the base substrate after completion of the desmear step,
and the conductive layer forming step comprises a seed layer forming process of forming a seed layer on the inner surface of the insulating layer and a conductor layer forming process of forming a conductor layer on the seed layer to provide the second conductive layer.

10. The method for manufacturing a packaging substrate according to claim 9,
wherein the seed layer comprises any one selected from the group consisting of titanium, tungsten, tantalum, molybdenum, nickel, chromium, and a combination thereof.
